(19) United States
(12) Patent Application Publication
(10) Pub. No.: US 2015/0062817 A1
(43) Pub. Date: Mar. 5, 2015

(54) SERVER

(71) Applicants: INVENTEC CORPORATION, Taipei (TW); Inventec (Pudong) Technology Corporation, Shanghai (CN)

(72) Inventors: Mao-Ching LIN, Taipei (TW); Kuo-Chin HUANG, Taipei (TW)

(73) Assignees: INVENTEC CORPORATION, Taipei (TW); Inventec (Pudong) Technology Corporation, Shanghai (CN)

(21) Appl. No.: 14/053,291

(22) Filed: Oct. 14, 2013

(30) Foreign Application Priority Data
Aug. 28, 2013 (CN) 201310382707.9

(51) Int. Cl. H05K 7/20

(52) U.S. Cl. CPC H05K 7/20254; H05K 7/20272
USPC 361/696; 361/720

(57) ABSTRACT

A server includes a housing, a motherboard and a heat dissipating module. The motherboard is disposed inside the housing and includes multiple heat sources. The heat dissipating module includes a cooling plate disposed inside the housing and in thermal contact with multiple heat sources. The cooling plate includes a substrate, a casing and multiple fins. The substrate is in thermal contact with multiple heat sources. The casing is disposed on the substrate, while the casing and the substrate form a chamber. Multiple fins are disposed on the substrate and are inside the chamber.

### CROSS-REFERENCE TO RELATED APPLICATIONS

This non-provisional application claims priority under 35 U.S.C. §119(a) on Patent Application No(s). 201310382707.9 filed in China, P.R.C. on Aug. 28, 2013, the entire contents of which are hereby incorporated by reference.

### BACKGROUND OF THE INVENTION

1. Technical Field of the Invention

The disclosure relates to a server, more particularly to a sever having a heat dissipating module.

2. Description of the Related Art

As information technology advances, the electronic devices are in widespread use. Meanwhile, for satisfying a variety of people's needs, the processing capabilities of the electronic devices are significantly improved by related developers. Take a server as an example. It can comprise multiple electronic devices (e.g., multiple central processing units, multiple storage devices, and multiple interface cards). Thereby, the processing speed, storage capability and the functions of the server can be improved.

Nevertheless, when the processing speed or the number of the electronic devices increases, the heat generated by the electronic devices increases accordingly. The rising temperature of the electronic devices may affect the normal operation of the server. Hence, a heat dissipating module having multiple fans is usually used to be disposed on the server, so as to accelerate the heat exchange of the electronic devices by the improvement of thermal convection. Thereby, the temperature of the server is reduced. In the related art, high power fans with bigger size are used to improve the heat dissipating efficiency, thereby reducing the temperature of the electronic devices. Additionally, increasing the number of the fans can also improve the heat dissipating efficiency and reduce the temperature of the electronic devices. However, adding additional fans or utilizing bigger fans with high powers may occupy more space where additional electronic device may be disposed and may even produce louder noise. Moreover, when the multiple electronic devices (e.g., two central processing units) are positioned at intervals, the present heat dissipating module cannot dissipate the heat generated from multiple electronic devices effectively simultaneously. Thus, it is required to develop a server and a heat dissipating module which can improve the heat dissipating efficiency without increasing the space for the heat dissipating module.

### SUMMARY OF THE INVENTION

A server comprises a housing, a motherboard and a heat dissipating module. The motherboard is disposed inside the housing and comprises a plurality of heat sources. The heat dissipating module comprises a cooling plate disposed inside the housing and in thermal contact with the plurality of heat sources. The cooling plate comprises a substrate, a casing and a plurality of fins. The substrate is in thermal contact with the plurality of heat sources. The casing is disposed on the substrate, while the casing and the substrate form a chamber. The plurality of fins are disposed on the substrate and are inside the chamber.

### BRIEF DESCRIPTION OF THE DRAWINGS

The disclosure will become more fully understood from the detailed description given herein below and the drawings are for illustration only, and thus do not limit the present disclosure, wherein:

FIG. 1 is a top view of a server according to an embodiment of the disclosure;

FIG. 2 is a perspective view of a cooling plate according to an embodiment of the disclosure; and

FIG. 3 is an exploded view of a cooling plate according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

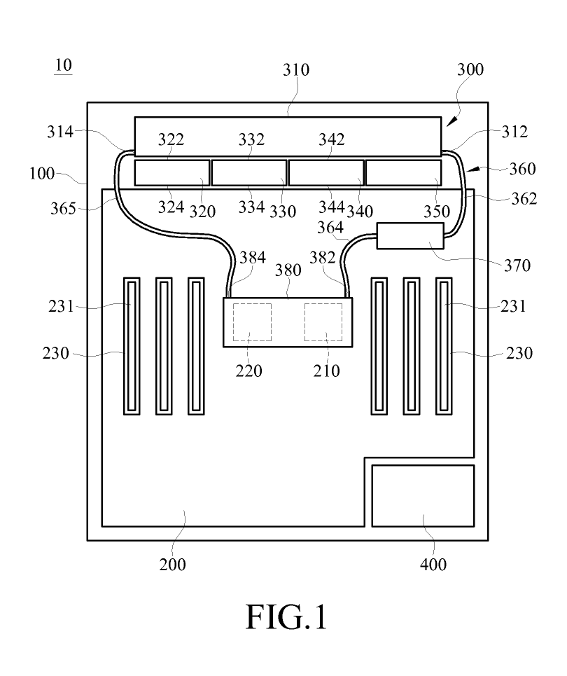

As seen in FIG. 1, a server 10 comprises a housing 100, a motherboard 200, a heat dissipating module 300 and a power supply 400.

In this embodiment, the motherboard 200 is disposed inside the housing 100. The motherboard 200 comprises two heat sources 210, 220, a plurality of sockets 230, a plurality of interface cards 231. The heat sources 210, 220 are spaced apart, namely they are separated by a distance. In this embodiment, both the heat sources 210, 220 are central processing units, but they are not limited thereto. In other embodiment, the heat source may be a chipset, a storage device or a power supply, and the number of the heat sources may be greater than two. When the server 10 operates, the heat sources 210, 220 generate heat due to being electrified. In this embodiment, the sockets are located on opposite sides of the hear sources 210, 220 respectively, while the interface cards are disposed on the sockets. When the server 10 operates, the interface cards 231 also generate heat due to being electrified.

In this embodiment, the heat dissipating module 300 is disposed inside the housing 100, but the location of the heat dissipating module 300 is not intended to limit the disclosure. The heat dissipating module 300 comprises a cooling plate 380, a liquid-cooling heat exchanger 310, a circulation line 360 and a plurality of fans 320, 330, 340, 350.

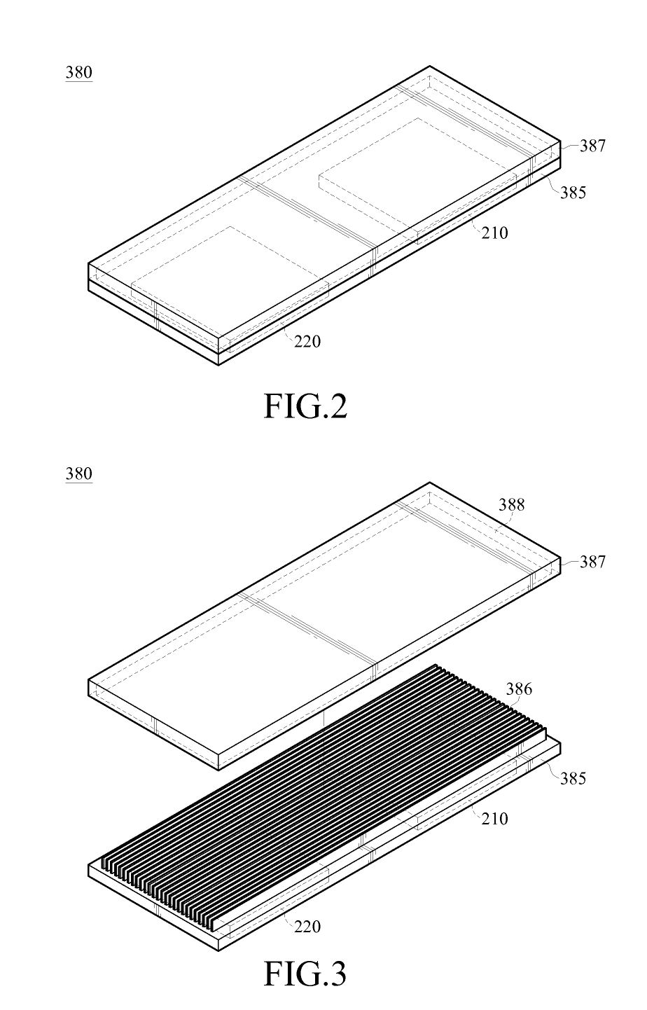

As seen in FIG. 1 to FIG. 3, the cooling plate 380 is in thermal contact with both heat sources 210, 220 simultaneously. In this embodiment, the cooling plate 380 comprises a water inlet end 382, a water outlet end 384, a substrate 385, a casing 387 and a plurality of fins 386. The substrate 385 is in thermal contact with both heat sources 210, 220 simultaneously. The housing 387 is disposed on the substrate 385. Consequently, the housing 387 and the substrate 385 together form a chamber 388, and the chamber 388 communicates the water inlet end 382 and the water outlet end 384. The fins 386 are disposed on the substrate 385 and are inside the chamber 388. The fins 386 extend from the heat source 210 to another heat source 220.

The liquid-cooling heat exchanger 310 is disposed on one side of the motherboard 200. Fans 320, 330, 340, 350 are near the liquid-cooling heat exchanger 310. The circulation line 360 connects the liquid-cooling heat exchanger 310 and the cooling plate 380. Therefore, the circulation line 360, the liquid-cooling heat exchanger 310 and the cooling plate 380 together form a circulation water line. A fluid can flow within the range of the circulation water line, so as to make the heat from the cooling plate 380 transfer to the liquid-cooling heat exchanger 310. The locations and the number of the liquid-cooling heat exchanger 310 and the fans 320, 330, 340, 350, however, are not intended to limit the disclosure. In other embodiments, the liquid-cooling heat exchanger 310 and the fans 320, 330, 340, 350 may be disposed on outside of the housing 100, and the number of fans 320, 330, 340, 350 may be greater than one, respectively.

The specific locations of the fans are set forth as follows. In this embodiment, fans 320, 330, 340, 350 are disposed between the liquid-cooling heat exchanger 310 and the cooling plate 380, and the fans 320, 330, 340, 350 are positioned side by side. The fans 320, 330, 340, for example, have one air inlet (namely 322, 332 and 342 respectively) and one air outlet (namely 324, 334 and 344 respectively). The air inlets 322, 332, 342 face the liquid-cooling heat exchanger 310. The air outlets 334, 344 face the heat source 210, while the air outlet 324 faces the socket 230. In this embodiment, the width of the liquid-cooling heat exchanger 310 is substantially equal to the total width of the fans 320, 330, 340, 350. Thereby, when the server 10 is operating, the fans 320, 330, 340, 350 are capable of improving the heat exchange between the liquid-cooling heat exchanger 310 and outside air.

In other embodiments, the heat dissipating module 300 further comprises at least one air duct (not shown in the figures), and the least one air duct are located on the air inlets 322, 332 and 342 respectively, or on the air outlets 324, 334 and 344 respectively. When being disposed on the air inlets 322, 332, 342 of the fans 320, 330, 340, the air ducts can guide outside air to the fans 320, 330, 340. When being disposed on the air outlets 324, 334 and 344 of the fans 320, 330, 340, the air ducts can guide airflow, and thereby improve the heat dissipation efficiency.

In this embodiment, the heat dissipating module 300 further comprises a water pump 370 disposed in the circulation water line 360. The liquid-cooling heat exchanger 310 has a water inlet 314 and a water outlet 312. The circulation water line 360 comprises a first pipe 362, a second pipe 364 and a third pipe 365. The opposite ends of the first pipe 362 are connected to the water outlet 312 of the liquid-cooling heat exchanger 310 and one end of the water pump 370 respectively; the opposite ends of the second pipe 364 are connected to the other end of the water pump 370 and the water inlet end 382 of the cooling plate 380; the opposite ends of the third pipe 365 are connected to the water outlet end 384 of the cooling plate 380 and the water inlet 314 of the liquid-cooling heat exchanger 310. In other words, the water pump 370 connects the water outlet 312 of the liquid-cooling heat exchanger 310 and the water inlet end 382 of the cooling plate 380.

The air supply 400 is disposed on the other side of the motherboard 200, but the number and the location of the air supply 400 can be amended when needed.

The processes of the heat dissipation performed by the heat dissipating module 300 are set forth below. Firstly, when the server 10 is operating, the electronic components on the heat sources 210, 220, interface card 231, power supply 400 and the motherboard 200 generate heat, accordingly. By the pumping force from the operation of the water pump 370, a fluid with lower temperature in the liquid-cooling heat exchanger 310 flows into the water pump 379 from the water outlet 312 via the first pipe 362. Subsequently, the fluid flows to the second pipe 364, water inlet end 382 and the cooling plate 380 in sequence. Since the heat sources 210, 220 are in thermal contact with the substrate 385 of the cooling plate 380 simultaneously, the heat generated by the heat sources 210, 220 transfers to the substrate 385. This leads to the heat exchange between the heat sources 210, 220 and the cooling plate 380. Then, the heat transfers from the substrate 385 to the fins 386. When the heat transfers to the fluid, the fluid absorbs the heat and the temperature thereof rises. As a result, the high temperature fluid flows from the water outlet end 384 of the cooling plate 380 to the water inlet 314 of the liquid-cooling heat exchanger 310 via the third pipe 365. The heat of the high temperature fluid transfers to the liquid-cooling heat exchanger 310 configured for performing heat exchange with outside air and thereby dissipating heat. Therefore, the temperature of the fluid drops rapidly. Furthermore, the operation of the fans 320, 330, 340, 350 can accelerate the heat convection with outside air. Fans, in the mean time, guide the outside air to the inside of the server 10, so that the heat exchange between the air and electronic components on the heat sources 210, 220, interface card 231, power supply 400 and motherboard 200 occurs for heat dissipation. Consequently, the temperature inside the server 10 decreases rapidly and this can maintain the stability of the server 10. After the temperature of the fluid inside the liquid-cooling heat exchanger 310 drops, the fluid is configured for flowing out from the liquid-cooling heat exchanger 310, so as to exchange heat with the cooling plate 380 again.

Overall, since the heat sources 210, 220 are main heat sources of the server 10, when the heat from the heat sources 210, 220 is taken away from the heat dissipating module 300, the temperature in the server 10 drops significantly. Therefore, the server 10 can work in a stable state. Even though the airflow, which is guided by the fans 320, 330, 340, 350 to the inside of the server 10, has absorbed the heat of the liquid-cooling heat exchanger 310, it does not affect the following heat exchange between the airflow and other electronic components in the server 10.

Moreover, since the cooling plate 380 is in thermal contact with the heat sources 210, 220 simultaneously, the heat dissipating module 300 can dissipate heat of the heat sources 210, 220 effectively. Also, the fins extends from heat source 210 to heat source 220, which utilizes the space between the heat sources 210, 220 to transfer heat. This increases the number and the heat dissipating area of the fins and therefore improve the heat dissipation efficiency overall.

Compared to the sever of the related art which has more fans or has fans with higher efficiencies (e.g., product number 4056 fan), the heat dissipating module 300 of the server 10 according to the disclosure has less fans and utilizes fans with lower efficiencies (e.g., product number 4028 fan) and smaller sizes. However, the heat dissipating module 300 of the disclosure can still improve the heat dissipation efficiency of the sever 10 effectively. As a result, the server can equip with additional electronic components or more central processing units to enhance the capability or operational efficiency of the server 10.

To sum up, in the server of the disclosure, the cooling plate is configured for being in thermal contact with multiple heat sources and the fins of the cooling plate extend from one heat source to another, so that the cooling plate can exchange heat with the multiple heat sources effectively. Therefore, compared to the related art, the cooling plate increases the quantity of the fins and the contact area thereof, so the heat is dissipated rapidly and the temperature drops quickly. That is, the heat dissipation efficiency of the server has been improved dramatically. Hence, the server of the disclosure solves the problem of the ineffective heat dissipation efficiency regarding the server of the related art. Furthermore, the operation of the fan(s) can accelerate the speed of the heat exchange between the liquid-cooling heat exchanger and outside air and improve the heat dissipation efficiency of the server. Moreover, the server of the disclosure reduces the number of the fans or the size of the fan, while improving the heat dissipation efficiency of the server and saving energy.

What is claimed is:

1. A server comprising:
a housing;
a motherboard disposed inside the housing, the motherboard comprising a plurality of heat sources; and
a heat dissipating module comprising a cooling plate disposed inside the housing and in thermal contact with the plurality of heat sources, and the cooling plate comprising:
a substrate in thermal contact with the plurality of heat sources;
a casing disposed on the substrate, the casing and the substrate forming a chamber; and
a plurality of fins disposed on the substrate and inside the chamber.

2. The server according to claim 1, wherein the heat dissipating module is disposed on one side of the motherboard.

3. The server according to claim 1, wherein the heat dissipating module further comprises:
a liquid-cooling heat exchanger;
a circulation line connecting the liquid-cooling heat exchanger and the cooling plate, so as to form a circulation water line; and
a plurality of fans near the liquid-cooling heat exchanger.

4. The server according to claim 3, wherein the plurality of fans are disposed between the liquid-cooling heat exchanger and the cooling plate.

5. The server according to claim 3, wherein the plurality of fans are arranged side by side.

6. The server according to claim 3, wherein each of the plurality of fans has an air inlet, and the air inlet faces the liquid-cooling heat exchanger.

7. The server according to claim 3, wherein the heat dissipating module further comprises a water pump disposed in the circulation line.

8. The server according to claim 1, wherein the plurality of fins extends from one of the plurality of heat sources towards the other of the plurality of heat sources.

9. The server according to claim 1, wherein two of the plurality of heat sources are separated by a distance,

10. The server according to claim 1, wherein the plurality of heat sources are a plurality of central processing units.
